(19) United States
(12) Patent Application Publication
(10) Pub. No.: US 2012/0111400 A1
(43) Pub. Date: May 10, 2012

(54) OPTICAL COATING

(75) Inventors: Gareth Wakefield, Oxford (GB); Martin Ryan Gardener, Banbury (GB); Jon-Paul Griffiths, Oxford (GB); Richards Charles Wincewicz, Bournemouth (GB); Tadeusz Antoni Podgorski, Pampisford (GB)

(73) Assignee: Oxford Energy Technologies, Ltd., Oxford (GB)

(21) Appl. No.: 13/144,943

(22) PCT Filed: Mar. 18, 2010
(86) PCT No.: PCT/GB2010/000490

§ 371 Date: Sep. 27, 2011

(30) Foreign Application Priority Data
Mar. 20, 2009 (GB) 09048703

(51) Int. Cl. H01L 31/0216; B32B 3/00; H01L 31/0232; B05D 5/06

(52) U.S. Cl. 136/256; 427/162; 428/149

(57) ABSTRACT

An optical coating, comprising porous particles, or formed from porous precursor particles. The average thickness of the coating is in the range of from 75 to 400 nm, and the surface roughness of the coating is in the range of from 2 to 300 nm. This coating provides broadband antireflective properties across the visible and near infrared part of the electromagnetic spectrum.

The invention relates to an optical coating, comprising porous particles or obtained from porous particles, that is transmissive preferably to visible light, and preferably provides antireflective properties, and optionally provides other additional functionality. The coating is particularly, but not exclusively, suitable for application to photovoltaic cells, displays, light emitting diodes and solar concentrators.

Solar cells are mainly fabricated on a glass substrate that is exposed to the environment. Typically, glass (or polymer) sheets reflect about 4-5% of incident sunlight on each surface—energy which is lost to a cell. Glass may be coated with an anti-reflective coating layer which reduces this to less than 2%. FIG. 1 illustrates schematically a conventional single-layer antireflective (AR) coating 1 on a substrate 2. The thickness of the AR coating 1 is d. The reflectance is reduced if the light reflected off the front and back surfaces of the AR coating 1 is arranged to destructively interfere. This is achieved (for normal incidence) if the thickness of the coating 1 is equal to a quarter of the wavelength of the incident light in the medium of the coating, i.e.:

$$d = \frac{1}{4} \frac{λ}{{n}_{1}}$$

where δ is the wavelength of the light in vacuum, and n₁ is the refractive index of the coating. This assumes that the refractive index n₁ of the coating 1 is less than the refractive index nₘ of the substrate 2, such that there is a π phase change of the light reflected at the interface between the coating 1 and the substrate 2. The thickness d may, of course, be any odd integer multiple of one quarter of the wavelength of the light in the coating. For complete destructive interference, the amplitude of the two reflected waves must be equal to each other. This can be achieved if the refractive indices are matched such that:

n₁/n₀=nₘ/n₁

rearranging this gives:

n₁=\sqrt{n₀nₘ}

For air n₀=1, and for glass nₘ=1.5, which gives the ideal refractive index of the coating as n₁=1.22.

In display applications, AR coatings are used to reduce reflectance which diminishes the viewability of the display i.e. reduce glare. Another desirable property of such coatings is a reduction in reflectance over a wide viewing angle. In such cases, the AR coating is primarily applied to plastic substrates although glass may also be used.

However, there are a number of problems with conventional AR coatings. There is difficulty in finding suitable coating materials with the desired low refractive index. The coatings are typically applied by techniques such as chemical vapour deposition (CVD) or physical vapour deposition (PVD) which require costly processing and are difficult to use with substrates other than glass, such as plastic windows for solar concentrators. However the relatively inert surface chemistry of typical polymeric materials used for these components can lead to poor adhesion of subsequently coated layers.

The above analysis shows that optimal antireflectance properties are only achieved at one wavelength for one particular angle of incidence; at other wavelengths and angles of incidence, the antireflectance deteriorates and so the efficiency of the solar cell or the readability of the display is reduced. Broadband AR coatings can be achieved by using multiple layers of differing refractive index, but this increases the complexity and cost of manufacture, which makes the solar cells or displays more expensive and less economically viable. There can also be problems with applying AR coatings in addition to other functional coatings that may desirably be present on the solar cell, such as so-called ‘self-cleaning’ coatings.

It is an object of the present invention to alleviate, at least partially, some or any of the above problems.

Accordingly, the present invention provides an optical coating comprising porous particles, wherein the average thickness of the coating is in the range from 75 to 400 nm, and wherein the surface roughness of the coating is in the range from 2 to 300 nm.

Preferably, the porous particles comprise at least one of mesoporous particles and microporous particles.

Preferably, the porous particles comprise at least one of zeolite particles, silica particles, and aluminosilicate particles.

The optical coating my be obtainable by treating a coating as specified above with an alkali or base solution, such as a solution comprising potassium hydroxide, sodium hydroxide or ammonium hydroxide.

Another aspect of the present invention provides a method of producing an optical coating comprising:
providing a blend of porous particles with a mixture of maximum dimensions in the range of from 10 to 70 nm; and
applying the particles to a substrate to form a layer with average thickness in the range of from 75 to 400 nm.

The invention extends the bandpass of the AR coating by providing a textured surface of varying thickness on a scale less than the wavelength of the incident light.

In the present specification, the term “optical” is used, for example in “optical coating”; however, this term is not intended to imply any limitation to visible light only. The invention may, if required, be applied to other parts of the electromagnetic spectrum, for example including at least ultraviolet (UV) and infrared (IR).

Embodiments of the invention will now be described, by way of example only, with reference to the accompanying drawings, in which:

FIG. 1 is a schematic illustration of a conventional uniform-thickness, single-layer AR coating provided on a substrate;

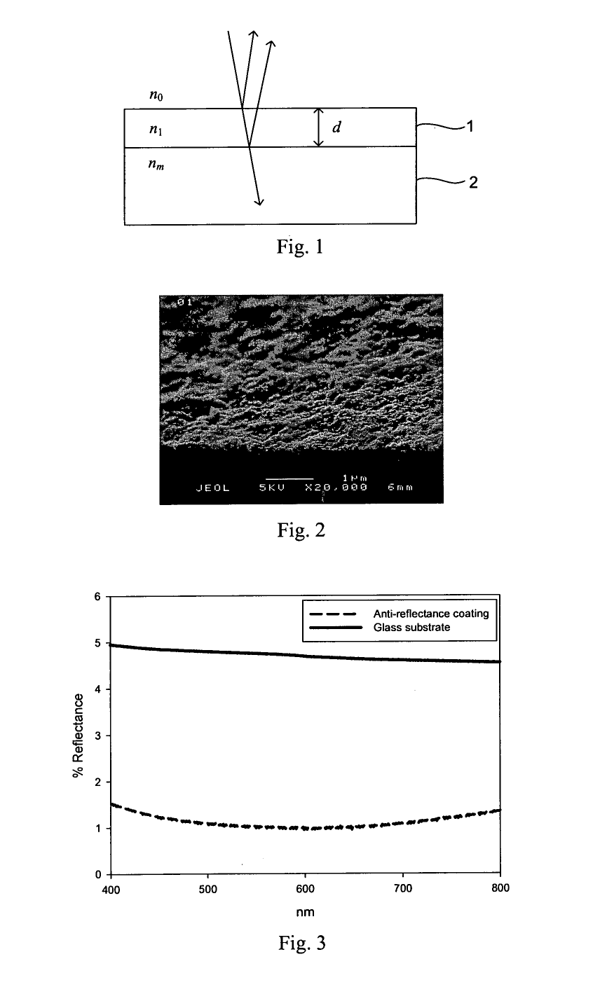

FIG. 2 is an electron-micrograph of an optical coating according to a first example embodying the invention;

FIG. 3 is a graph of reflectance (%) against wavelength of incident light (nm) for a borosilicate glass substrate coated with an AR coating according to the first example embodying the invention (lower plot) and for an uncoated substrate (upper plot);

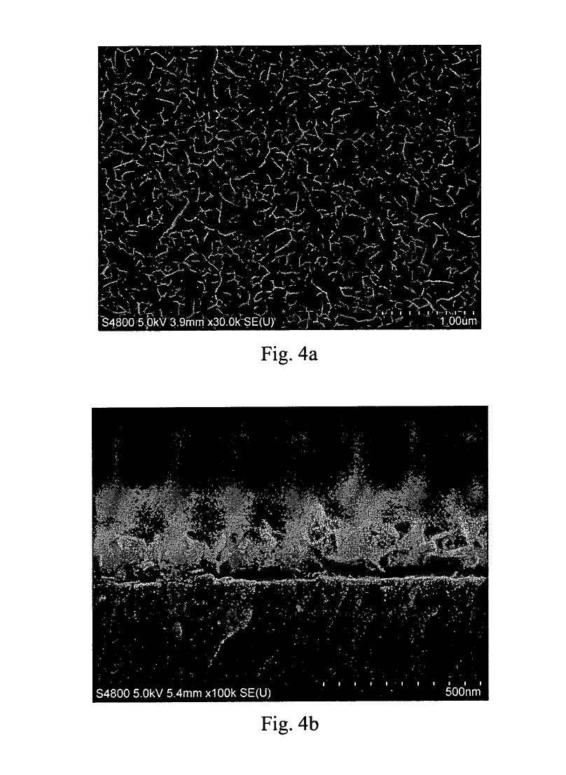

FIG. 4a is an electron-micrograph of an optical coating according to a second example embodying the invention in plan view;

FIG. 4b is an electron-micrograph of the optical coating according to the second example embodying the invention in cross-section;

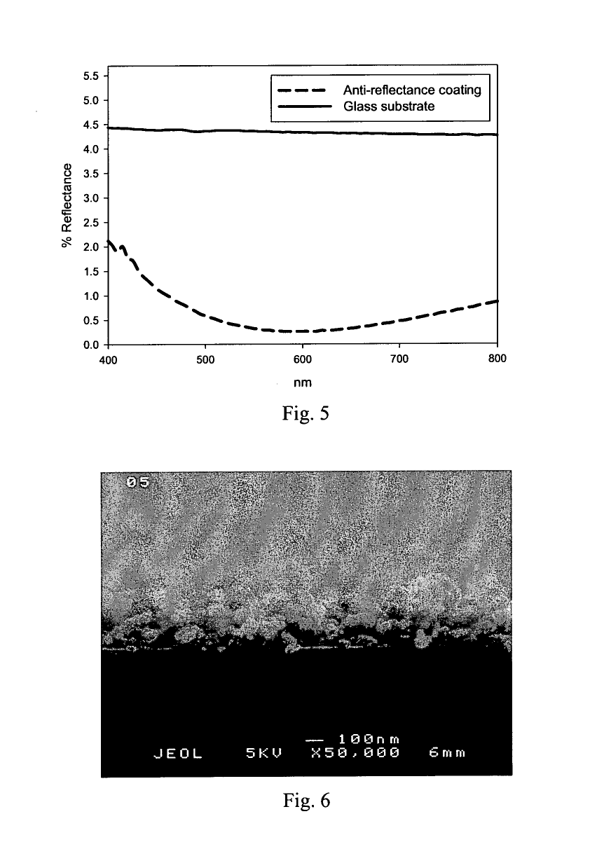

FIG. 5 is a graph of reflectance (%) against wavelength of incident light (nm) for a borosilicate glass substrate coated with an AR coating according to the second example embodying the invention (lower plot) and for an uncoated substrate (upper plot);

FIG. 6 is an electron-micrograph of the optical coating according to a third example embodying the invention in cross-section;

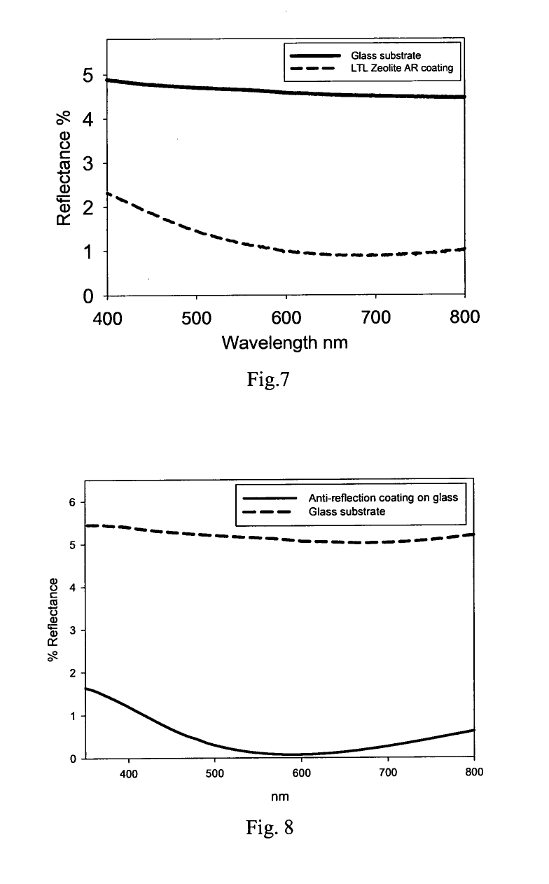

FIG. 7 is a graph of reflectance (%) against wavelength of incident light (nm) for a glass substrate coated with an AR coating according to the third example embodying the invention (lower plot) and for an uncoated substrate (upper plot); and

FIG. 8 is a graph of reflectance (%) against wavelength of incident light (nm) for a glass substrate coated with an AR coating according to the fourth example embodying the invention (lower plot) and for an uncoated substrate (upper plot)

The preferred embodiment of the optical coating relates to the use of porous nanoparticles in an antireflectance coating or as a precursor to forming an antireflectance coating. The particles have an open or porous structure. Porous particles are used as antireflectance coatings because the porous nature of the material naturally reduces the refractive index (i.e. the refractive index becomes a average of that of air and the material of the particles). As such they may be applied to a surface and fulfil the requirements of having a refractive index close to halfway between glass and air. The particles may be mesoporous (with pore diameters greater than 2 nm) or microporous (with pore diameters less than 2 nm). In general, the particles are less than 100 nm in maximum dimension and have a regular pore structure with pore diameter less than 10 nm.

Suitable materials for the porous particles include silica or aluminosilicate materials, examples of which are zeolites. Preferred materials for the porous particles are based on pure silica or silica with low levels of alumina. Specific examples include: LTL zeolites, which are 100% silica and have a space group of P6/mmm, or LTA zeolites. Other examples are mesoporous materials, which are not classed as zeolites because of their larger pore size, for example pore diameter in the range 2 to 10 nm. A preferred mesoporous material is composed of pure silica, and a preferred pore size is 3 nm. Suitable porous particles are commercially available.

According to this embodiment of the invention, a blend of porous silica particles or aluminosilicate particles is used to create an anti-reflectance coating with a broad transmission bandwidth. The particles comprise a blend of different sizes (maximum dimensions) preferably spanning the range from 10 to 70 nm, to improve the bandwidth for an AR coating, but could comprise a mix of particles of 40 nm and 50 nm (or other intermediate values within the range 10 to 70 nm) which would lower the roughness and hence transmission bandwidth of the final film, but with improved abrasion resistance. The particles are used to create a layer on a substrate, such as glass or polymer, which has a mean thickness in the range from 75 to 400 nm, with a surface roughness in the range from 2 to 300 nm and a refractive index in the range of 1.1 to 1.4. A more preferred value for the thickness is in the range from 100 to 200 nm. A more preferred surface roughness is in the range from 10 to 150 nm, most preferably 20 to 80 nm.

The layer is formed on the substrate by a wet-processing technique, such as spraying, spin-coating or dip-coating, using a suspension of the porous particles and a binder material. The binder can impart mechanical strength to the coating. Preferred embodiments of the binder are silicate based, silica, silicone based, siloxane based or acrylate based. The surface roughness forms spontaneously upon deposition of the layer because of the range of dimensions of the starting particles. The particles are attached to each other and bound together in a robust structure, preferably using silane chemistry. In the preferred embodiment, tetraethyl orthosilicate is formulated with water, alcohol and acid and spin coated onto the substrate in a pre-treatment step to provide an interface region that sticks the particles to the substrate. The optical layer may optionally undergo a further chemical bath treatment, for example with an alkali or base solution, such as a 0.1M KOH bath, a 0.1M NaOH bath or a 0.1M NH₄OH bath, to bind the particles together. The chemical bath treatment is preferably, but not restricted to, a water-based solution. After chemical bath treatment the structure of the film is altered and the scratch resistance increased. Such a layer reduces reflectance throughout the visible part of the spectrum (wavelength range 400 to 700 nm) by over 80% on conventional glass surfaces.

The preferred embodiment of the surface treatment is one in which the surface modification that is carried out introduces a chemical functional group to the substrate surface which is able to chemically bond, either co-valently or ionically, with the binder system. The choice of such functionality would be known to an individual skilled in the art. Suitable surface modification techniques include, but are not limited to, plasma, corona or flame treatment or reaction of the surface with a reactive intermediate such as an organic radical, carbene or nitrene.

### EXAMPLE 1

### Anti-Reflectance Film Based on Mesoporous Silica Nanoparticles

A specific example, embodying the invention, of an AR coating based on mesoporous silica nanoparticles, and method of making the same, is as follows: Particles comprised of mesoporous silica are formed into a 150 nm layer on a borosilicate glass substrate from a suspension of the particles as follows: 100 μl of 0.75% w/v mesoporous silica in methanol is spun onto a glass substrate at 4000 rpm for 10 seconds. The particles are primarily cubic or rectangular and comprise a blend of different size particles having a maximum dimension typically in the range from 25 to 50 nm. The surface roughness, as measured by white light interferometry, is 80 nm. Further information on the interferometry can be found at http://www.optics.arizona.edu/jcwyant/pdf/meeting_papers/whitelightinterferometry.pdf. FIG. 2 is an electron-micrograph of the layer, and FIG. 3 is a graph of the reflectivity at near normal incidence in the visible part of the spectrum for the layer on the substrate (lower plot) in comparison with an uncoated glass substrate (upper plot).

Spectroscopic ellipsometry measurements on the layer show that the refractive index (at 500 nm) is in the range 1.10 to 1.15.

### EXAMPLE 2

### Anti-Reflectance Film Obtained from Mesoporous Silica Nanoparticles as Precursor to the Film

A film of mesoporous silica particles of 25 to 50 nm is spin-coated on to a glass surface that has been treated with a tetraethylorthosilicate (TEOS) solution of 2:40:1 of TEOS:Isopropyl alcohol:0.1M HCl. The silica particles are suspended as 0.75% w/v particles in methanol and 100 μl is flooded on to the surface of a substrate spinning at 4000 rpm to produce the film. After drying the coating is immersed in a 0.1M KOH solution for 24 hours at 80° C. to produce the final film that passes ASTM Standard Pencil Hardness Test D3363-05 to 5H. In FIG. 4a a plan view of the film is shown and FIG. 4b shows the cross-section. The reflectivity is given in FIG. 5 (lower plot)—the minimum being 0.25% at 550 nm—the reflectivity of an uncoated substrate is also given in FIG. 5 for comparison (upper plot). The KOH treatment shows considerable modification of the structure indicating that the structure comprising the porous particles acts as a precursor to the final structure of the film.

### EXAMPLE 3

### LTL Nanozeolite Film as Anti-Reflectance Coating

A solution of 1% w/v LTL zeolites of particle size 10 to 70 nm are formulated as 25% zeolite formulation, 25% methanol and 50% isopropyl alcohol. This solution is spun down on to a glass substrate at 1000 rpm for 60 seconds. The film is dried and the spinning process is repeated until 5 layers have been formed. The structure of the film is shown in cross-section in FIG. 6 and the reflectance properties in comparison to a clean glass slide is shown in FIG. 7.

### EXAMPLE 4

### Anti-Reflectance Coating Obtained from Mesoporous Silica Nanoparticles Incorporating Surface and Bulk Binder Material

A solution of 1.4% w/v mesoporous silica in methanol is used as a source of particles (Solution A). The size range of the mesoporous silica particles is 20-30 nm. A binder solution comprising 100 μl tetraethyl orthosilicate (TEOS), 2 ml isopropanol (IPA) and 50 μl hydrochloric acid is prepared (Solution B). Glass substrates are prepared by washing in acetone at 60 C for 10 minutes, IPA at 60 C for 10 minutes and are then dried. The dimensions of the substrates are 25 mm×25 mm. The anti-reflection coating is prepared using a spin coater. A substrate is spun at 4200 rpm and 270 μl of Solution B is deposited on the substrate which continues spinning for 25 seconds. Following this 270 μl of Solution A is deposited on the substrate which is spun at 4200 rpm for 25 seconds. These two deposition steps are then repeated to give a final coating with the correct optical and mechanical properties. The reflectance properties in comparison to a glass substrate are given in FIG. 8.

### Applications

The preferred application of the optical coating is on a glass window on top of a photovoltaic solar cell. The solar cell may be of any suitable kind, such as monocrystalline silicon, polycrystalline silicon, thin-film silicon and hybrid technologies. The optical coating may be used on other optical components, known as solar concentrators, used for collecting and directing sun light to a photovoltaic cell. Suitable polymer materials for such components include, but are not limited to, polyesters such as polyethylene terephthalate (PET) and polyethylene naphthalate (PEN), and polyolefins such as biaxially oriented polypropylene (BOPP). However, the optical coating embodying the invention may also be used in general displays, and general window applications—for example for thermal management of buildings. An optical coating embodying the invention can also be employed in ophthalmic elements, whether made of glass or plastics materials, for example spectacle lenses.

The same properties that make the optical coating excellent for antireflectance also, of course, mean that the coating can be employed to achieve good efficiency in light emission applications, especially broad band light emission, such as for colour displays, lighting in general, particularly white lighting, and so on. In these cases, the substrate may be made of glass or plastics materials, for example polycarbonate and polymethylmethacrylate (PMMA), though these materials can, of course, be used in solar cells too.

Further embodiments of the current invention also include multiple layer coatings based on nanoparticle and thin films that also include an anti-reflectance component on the outer layer as described above. This ability to combine and integrate optical management properties is unique and only available as a result of the nanoparticle based AR coating—in this way one can use certain desired optical properties of materials but minimise the effect of changes in the refractive index of the materials that have precluded the use of these materials in solar cell and other windows to date.

Particular further embodiments will now be described with reference to the optical and/or physio-chemical properties additional to antireflectance that are employed.

### 1. Ultraviolet Screening.

Some types of solar cells, for instance dye sensitised cells, require that the UV light be screened out due to its detrimental effects on device performance. Typical compounds used include TiO₂ and ZnO. However, merely coating a glass substrate with a TiO₂ layer (refractive index 2.7) can increase the reflectance of the window by up to 21% under incident light. Consequently, the additional functionality of an anti-reflective coating as described above is used for maintaining cell efficiency.

### 2. Down Conversion of Incident Light.

A major source of reduced efficiencies in solar cells comes as a result of phonons generated by thermalization of charge carriers within the conduction band of the absorbing semiconductor—this may be reduced by including a down conversion layer on top of the semiconductor window. This would typically convert UV to blue, blue to green, UV to red etc. Any material that will down convert from a higher frequency photon is useful—these materials are typically based on phosphor materials such as YAG:Ce, Y₂SiO₅:Ce or other luminescent oxides. As these materials have a higher refractive index than glass they can be coated with an anti-reflective coating according to the invention.

A particular embodiment of this invention concerns dye sensitised solar cells—as mentioned previously there is a need to eliminate UV light from the cell. However, cell efficiency may be increased by converting the incident solar UV light to a less damaging wavelength—especially blue light in the region 400-450 nm. This may be achieved by using a luminescent material with broad band absorption in the near UV (290-400 nm) and converting via a small Stokes shift into emission at 400-450 nm. Typically materials include CaWO₄ and Y₂SiO₅:Ce which are near UV excited blue emitters. As before, these are used in conjunction with AR coatings as described above.

### 3. Hydrophobic Self-Cleaning Coatings

Contamination of solar cell surfaces with organic matter and dust is a serious problem leading to significant drop-off in cell external efficiency and the implementation of expensive cleaning regimes. A hydrophobic surface improves rain water run off from the cell surface—this acts to pick up dust and organic matter and retains window transmission properties. An addition to the anti-reflectance coating involves a chemical modification to the surface to render the surface permanently hydrophobic by covalent insertion of a group containing a hydrophobic tail component and reactive head component covalently bonded to one another. Such hydrophobic substituents are typically, but not limited to, non-polar or fluorinated compounds such as aromatic rings, silicone waxes, alkyl chains of various lengths with or without fluorine atoms in the organic structure. Suitable reactive head groups include, but are not limited to, silanes, silazanes, radicals, carbenes and nitrenes.

### 4. Quantum Cutting of Incident UV Light

Quantum cutting refers to the phenomena whereby an incident photon is absorbed by a luminescence material—usually, although not always, based on rare earth elements—which then emits two photons generating a quantum efficiency >100%. Energy is conserved however, as the energy of the incident photon must be equal to or greater than twice the energy of the emitted photons. The applications of this phenomenon to solar cells are clear—an incident photon, split into two photons with energy higher than the band gap of the semiconductor absorber, will generate twice as much current per photon with a quantum cutting layer present. This layer is combined with an anti-reflectance layer to maximise light into the cell. Suitable quantum cutting systems can be based on wide band gap semiconductors, such as TiO₂, in conjunction with one or more rare earth ions.

### 5. Infra-Red Reflection

An infrared reflecting layer in conjunction with an AR coating can be used to manage heat transfer within the cell on both module and concentrator photovoltaic systems. Heat generation within solar cells creates phonons within the semiconductor that act to scatter electrons and increase resistivity. Suitable IR reflecting compounds which can be used include, indium tin oxide, zinc aluminium oxide, fluorine doped tin oxide, but other n-type and p-type wide band gap semiconductors can be used.

### 6. Photocatalytic Anti-Reflectance Coatings

Self cleaning glass may also be made by coating with a thin film of titanium dioxide, which absorbs UV photons to produce electron-hole pairs which have a high probability of recombining via surface states and producing free radicals which break down organic contaminants. This would, of course, be advantageous for solar cells—however the high refractive index of titanium dioxide would mean that the glass would have a reflectivity of over 20%. A further complication is that the titanium dioxide must have direct contact to the organic contaminant to be effective, so one cannot simply overcoat TiO₂ with an AR coating. An effective coating can be made using porous nanoparticles of the type described herein blended with TiO₂ particles, in which multiple layers of nanoparticles are placed down and the ratio of TiO₂ to porous particles is varied from high to low as one moves away from the glass surface. Thus there is a gradient of the ratio of TiO₂ to porous particles, maximum at the interface with the glass substrate and minimum at the top (exposed) surface. These layers are porous so access to the TiO₂ particles is maintained, but the refractive index is graded from high to low across the coating so that it is anti-reflective.

The above-described further functional layers, can, of course, be used in any combination with each other along with the porous particle-based AR coating.

1. An optical coating comprising:
porous silica particles;
wherein the average thickness of the coating is in the range from 75 to 400 nm; and
wherein the surface roughness of the coating is in the range from 2 to 300 nm.

2. An optical coating according to claim 1, wherein the refractive index of the coating is in the range of from 1.0 to 1.4.

3. An optical coating according to claim 1, which is an antireflective coating.

4. An optical coating according to claim 1, wherein the reflectance for incident light with a wavelength in the range from 450 nm to 700 nm is less than 2%, preferably less than 1.5%.

5. An optical coating according to claim 1, wherein the surface roughness of the coating is in the range from 10 to 150 nm, and optionally in the range from 20 to 80 nm.

6. An optical coating according to claim 1, comprising at least one of the following further layers:
an ultraviolet screening layer;
a down-conversion layer;
a hydrophobic layer;
a quantum cutting layer;
an infrared reflection layer; or
a photocatalytic layer.

7. An optical coating according to claim 6, wherein the porous particles are provided on the surface of one said further layer.

8. An optical coating according to claim 6, wherein the porous particles are integrated into at least one said further layer.

9. An optical coating according to claim 1, wherein the porous particles comprise mesoporous silica particles.

10. A solar cell comprising an optical coating according to claim 1.

11. A display comprising an optical coating according to claim 1.

12. A lighting component comprising an optical coating according to claim 1.

13. An ophthalmic element comprising an optical coating according to claim 1.

14. A method of producing an optical coating comprising:
providing a blend of porous silica particles with a mixture of maximum dimensions in the range from 10 to 70 nm; and
applying the particles to a substrate to form a layer with average thickness in the range from 75 to 400 nm.

15. A method according to claim 14, further comprising adding a binder material surrounding the silica particles.

16. A method according to claim 15 wherein the binder is at least one of: silicate based, silica, silicone based, siloxane based or acrylate based.

17. A method according to claim 14, further comprising pre-treating the substrate to chemically bond the particles to the substrate.

18. A method according to claim 14, wherein the porous particles comprise mesoporous silica particles.
